(19) United States
(12) Patent Application Publication
(10) Pub. No.: US 2008/0093639 A1
(43) Pub. Date: Apr. 24, 2008

(54) METHOD FOR FORMING GATE INSULATING LAYER OF MOS TRANSISTOR

(76) Inventor: Dae-Young Kim, Chungcheongnam-do (KR)

Correspondence Address: SHERR & NOURSE, PLLC, 620 HERNDON PARKWAY, SUITE 200, HERNDON, VA, 20170, US

(21) Appl. No.: 11/870,175

(22) Filed: Oct. 10, 2007

(30) Foreign Application Priority Data
Oct. 20, 2006 (KR) 10-2006-0102210

(51) Int. Cl. H01L 29/94; H01L 21/31

(52) U.S. Cl. 257/288; 438/783; 257/E29.345; 257/E21.24

(57) ABSTRACT

A method for forming a gate insulating layer of a Metal Oxide Semiconductor (MOS) transistor includes forming an oxide layer on a semiconductor substrate, implanting plasma nitrogen ions into the oxide layer, and performing heat treatment on the nitrogen ion-implanted oxide layer to eliminate damage to a surface of the oxide layer. The nitrogen ions are implanted according to a Decoupled Plasma Nitridation (DPN) method. The nitrogen ions are implanted under conditions including RF power of approximately 200-800 W, a duty cycle of approximately 20-100%, a pressure of approximately 10-30 mtorr, and a process time of approximately 30-100 seconds.

This application claims the benefit under 35 U.S.C. §119 of Korean Patent Application No. 10-2006-0102210, filed on Oct. 20, 2006, which is hereby incorporated by reference in its entirety.

### BACKGROUND

Recently, the channel size of some semiconductor devices, particularly MOS transistors, has been reduced below 90 nm, which can cause problems such as an increase in the leakage current of gate oxide layers and boron penetration of P-channel MOS transistors. Attempts have been made to apply a gate oxide layer containing a large amount of nitrogen as a solution to these problems. However, the conventional method for forming a nitrogen oxide layer through thermal decomposition of NO or N₂O under a high temperature atmosphere has limitations in implanting a large amount of nitrogen into the gate oxide layer and also has a problem in that nitrogen is concentrated on a channel interface in the gate oxide layer.

### SUMMARY

Embodiments relate to a gate insulating layer of a semiconductor device that includes an oxide layer on a semiconductor substrate, implanted plasma nitrogen ions within the oxide layer; and a heat treated surface of the nitrogen ion-implanted oxide layer thereby reducing damage to the surface.

Embodiments relate to a method for forming a gate insulating layer of a semiconductor device that includes forming an oxide layer on a semiconductor substrate; implanting plasma nitrogen ions into the oxide layer; and performing heat treatment on the nitrogen ion-implanted oxide layer to eliminate damage to a surface of the oxide layer.

### DRAWINGS

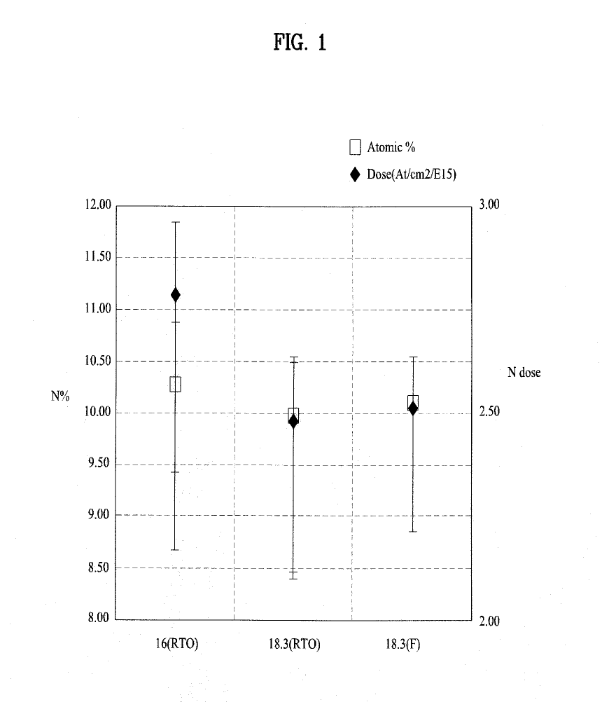

Example FIG. 1 is a graph showing analysis results of nitrogen concentration according to the thickness of a gate oxide layer;

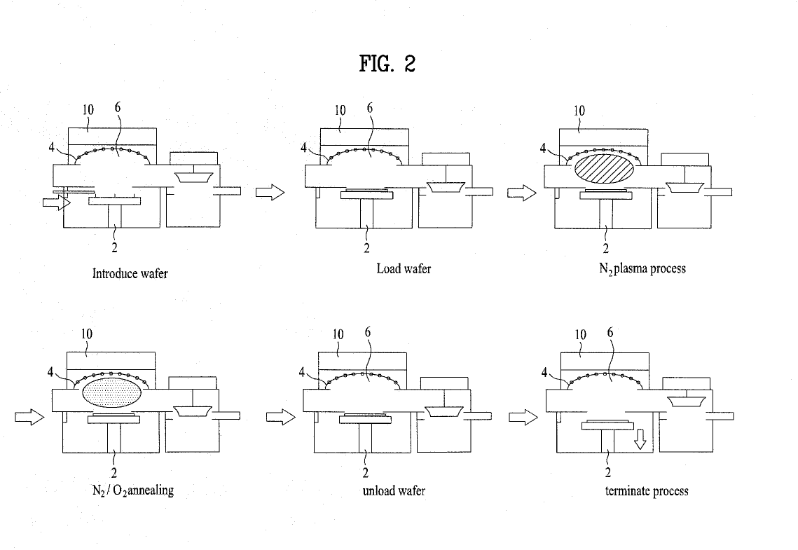

Example FIG. 2 is a process flow diagram illustrating a process for forming a gate insulating layer according to embodiments.

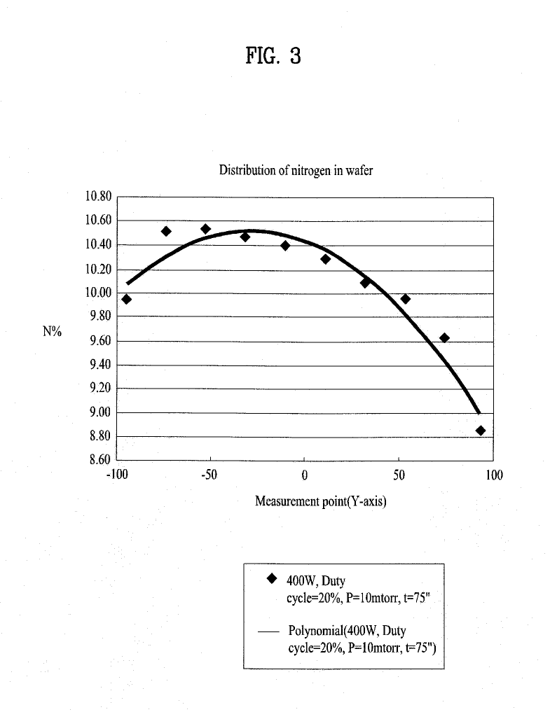

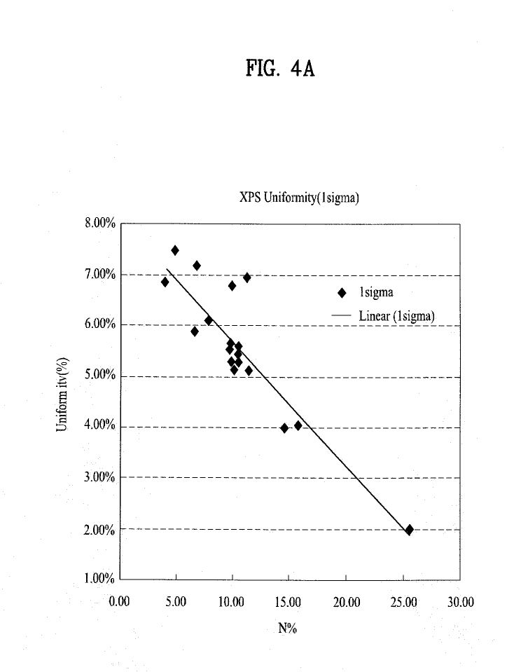

Example FIG. 3 is a graph showing a distribution of concentration of nitrogen implanted into a wafer.

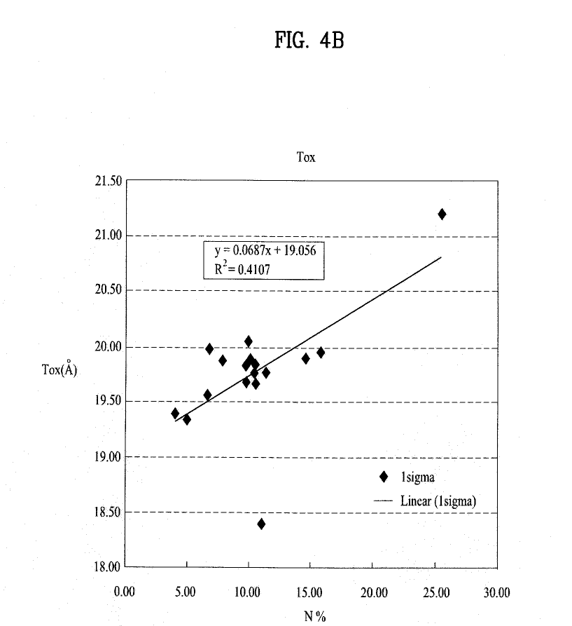

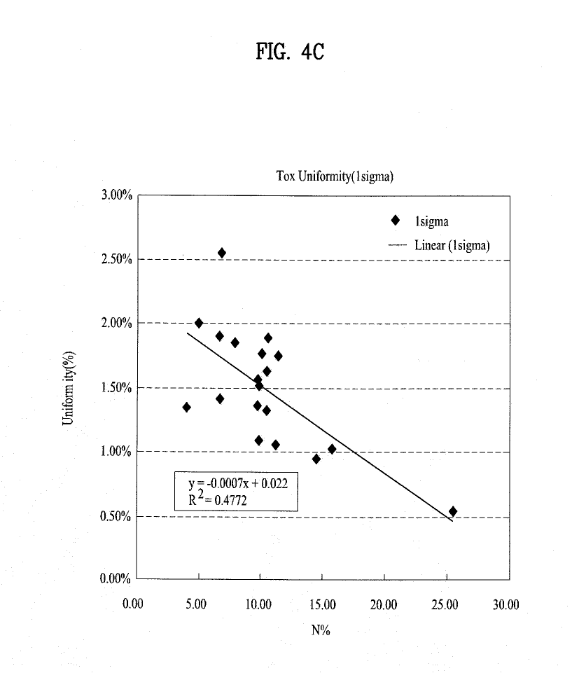

Example FIGS. 4A to 4C are graphs showing changes in the thickness and the uniformity of a gate oxide layer according to nitrogen concentration.

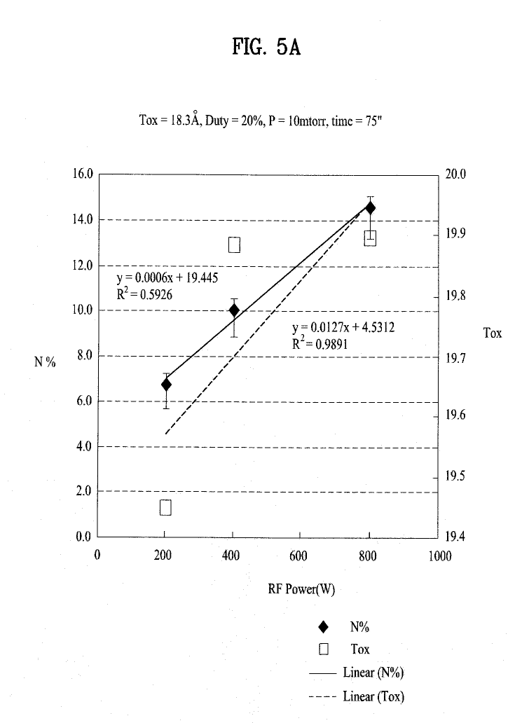

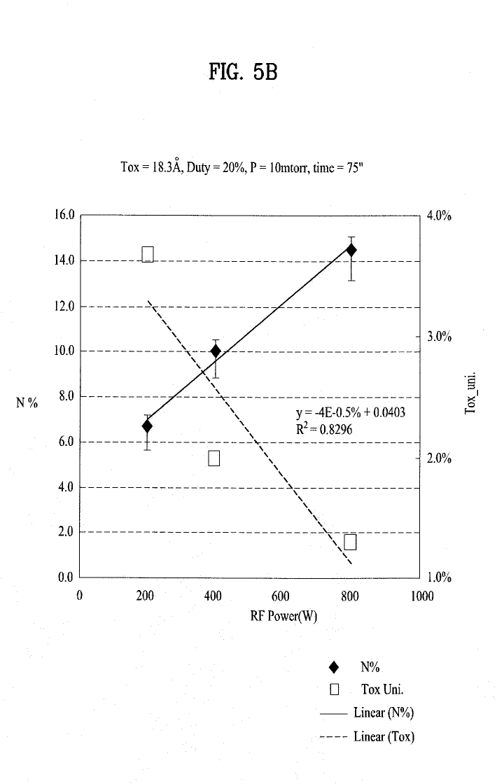

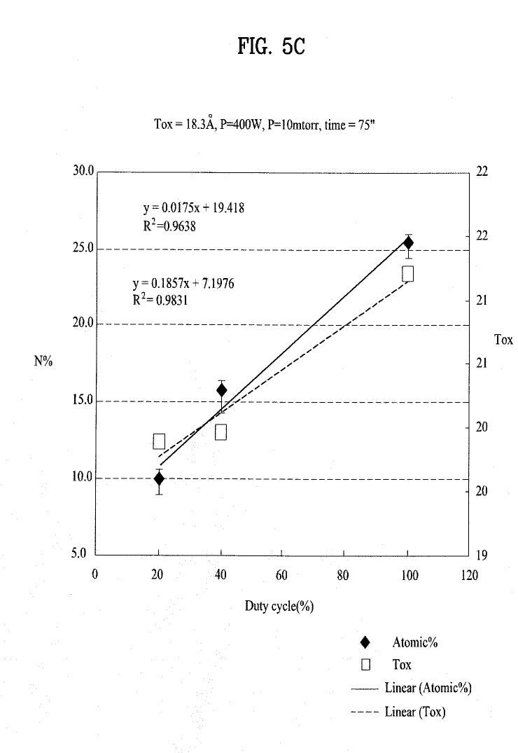

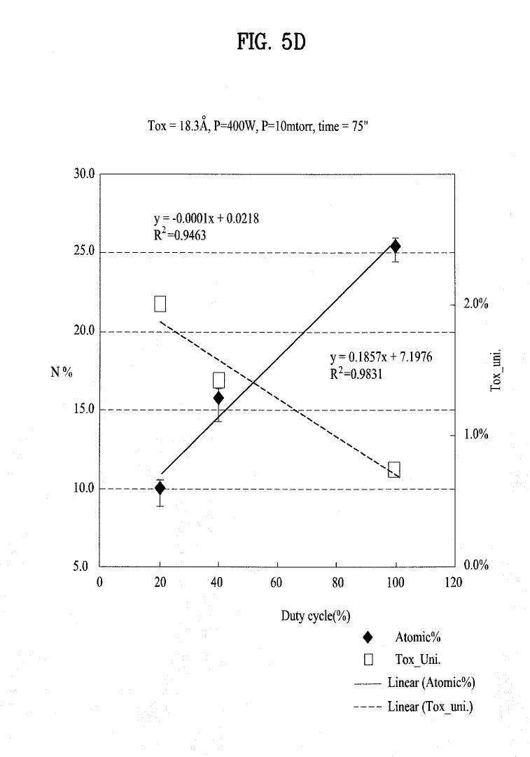

Example FIGS. 5A to 5D are graphs showing changes in the thickness and the nitrogen concentration of a gate oxide layer according to RF power.

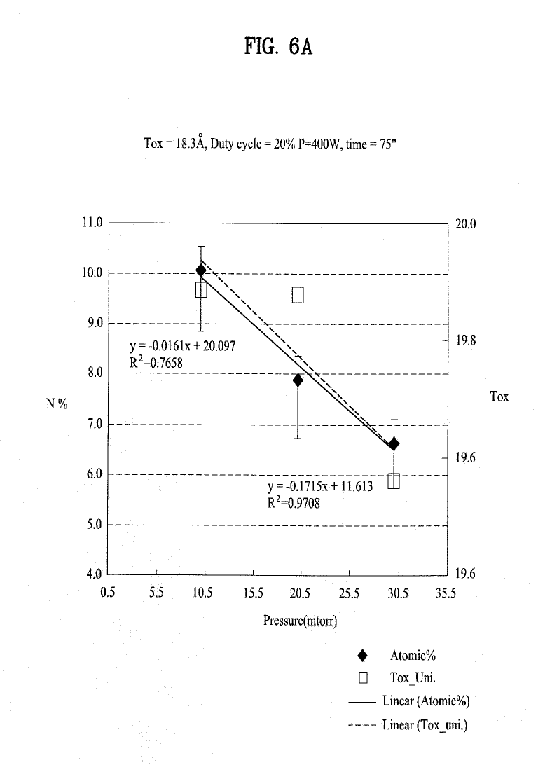

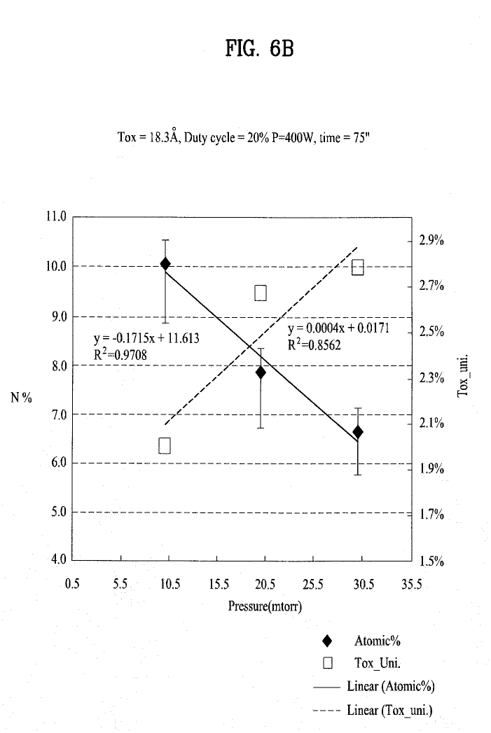

Example FIGS. 6A and 6B are graphs showing changes in the thickness and the nitrogen concentration of a gate oxide layer according to a process pressure.

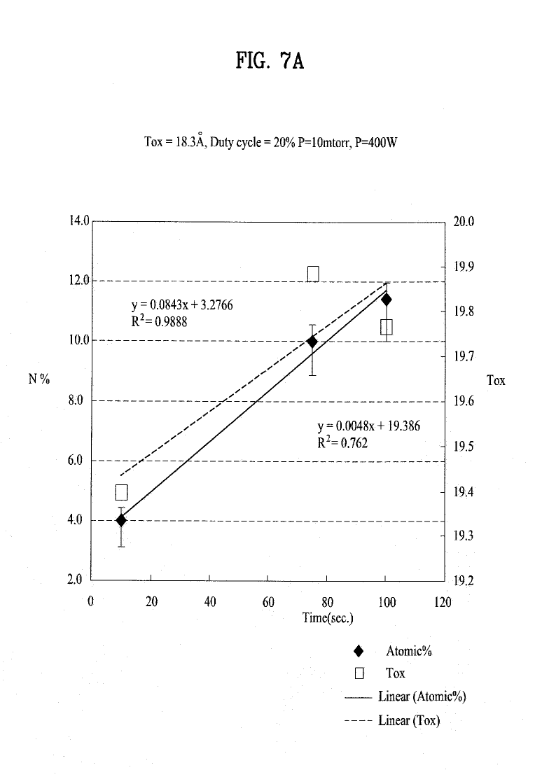

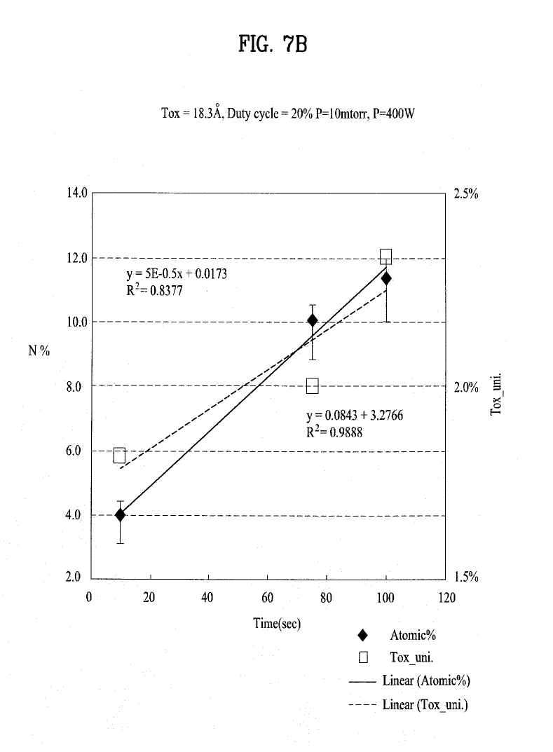

Example FIGS. 7A and 7B are graphs showing changes in the thickness and the nitrogen concentration of a gate oxide layer according to a process time.

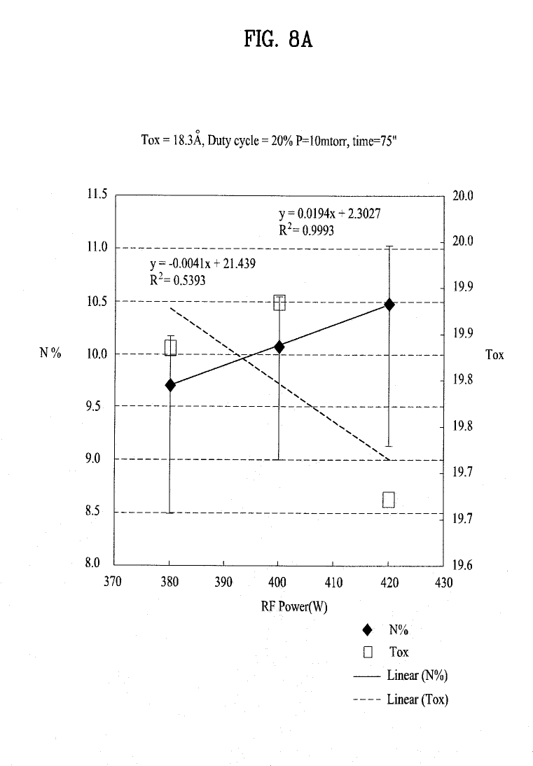

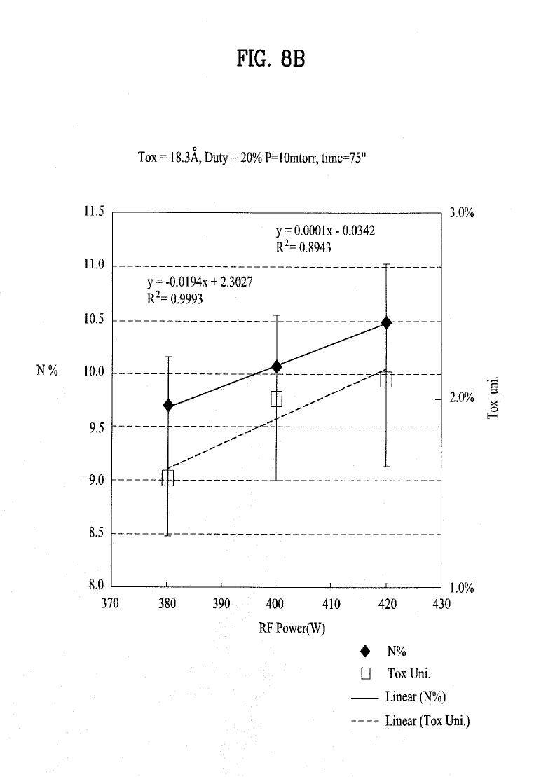

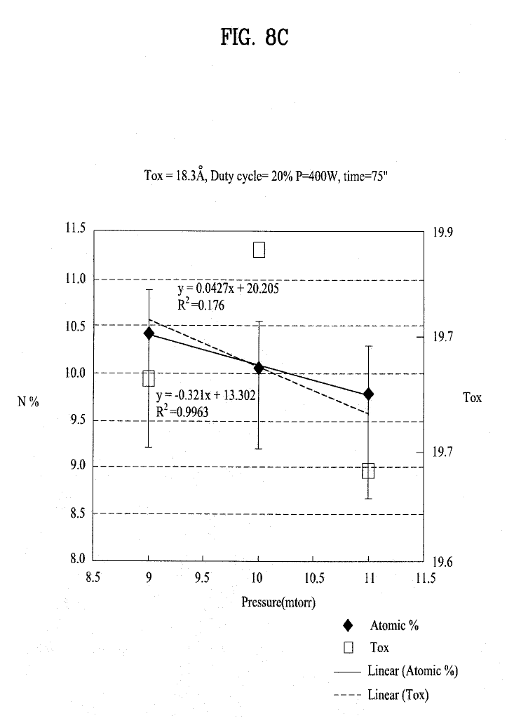

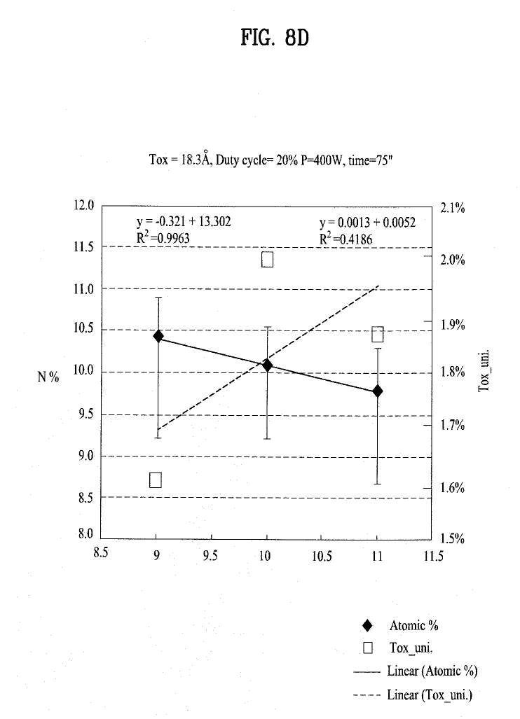

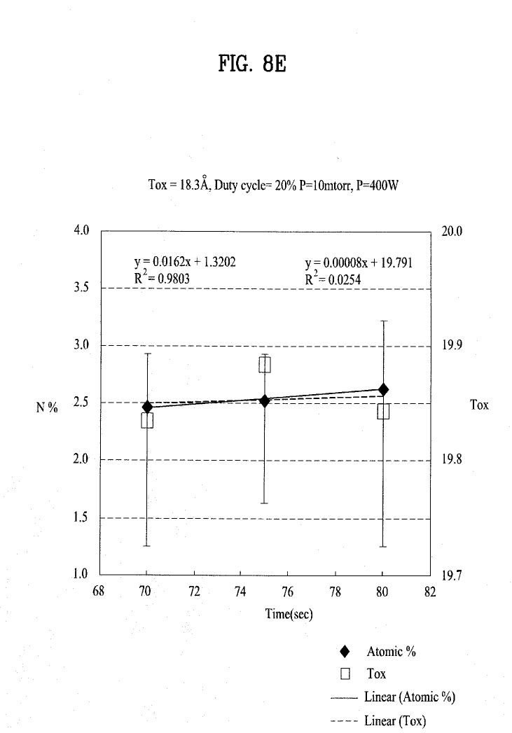

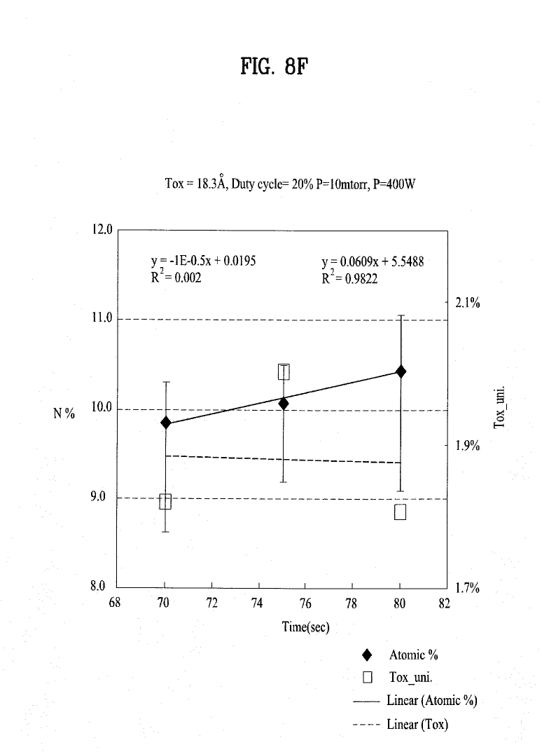

Example FIGS. 8A to 8F are graphs showing changes in the thickness and the nitrogen concentration of a gate oxide layer according to changes of process parameters in a small range.

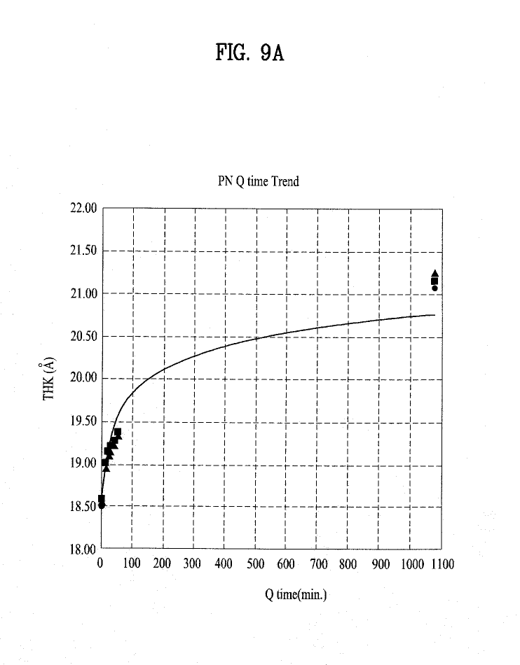

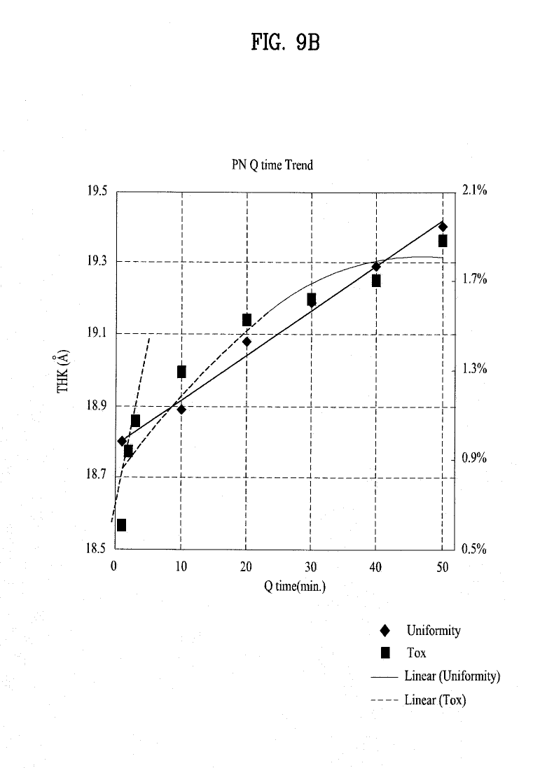

Example FIGS. 9a and 9B are graphs showing the influence of organic materials on a wafer when the wafer is exposed to the air.

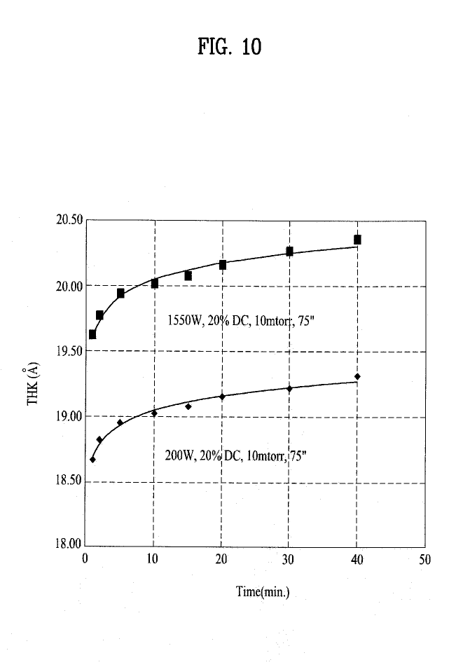

Example FIG. 10 is one graph showing changes in the thickness of a gate oxide layer according to RF power.

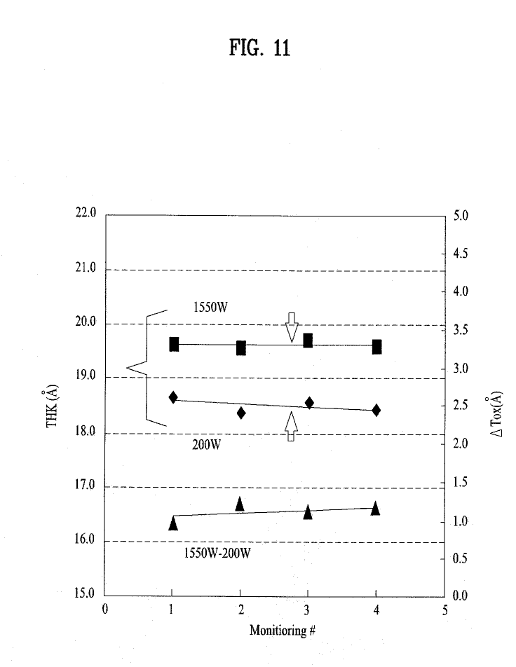

Example FIG. 11 is another graph showing changes in the thickness of a gate oxide layer according to RF power.

### DESCRIPTION

An alternative method, to that described earlier, is to implant nitrogen into the gate oxide layer using plasma implantation. This nitrogen implantation using plasma allows nitrogen distribution to be concentrated near the surface of the oxide layer to effectively prevent boron penetration and to accomplish a gate oxide layer that contains a large amount of nitrogen and thus has a high permittivity.

The plasma technology for gate insulating layers can use two methods, a Remote Plasma Nitridation (RPN) method and a Decoupled Plasma Nitridation (DPN). Usually, the DPN method is used to distribute high-density nitrogen uniformly in a very thin oxide layer that is 2 nm thick or less. The concentration of nitrogen implanted using the DPN method greatly varies depending on process parameters such as RF power, an RF duty cycle, a process pressure, and a process time. Management of these process parameters is essential in determining the electrical oxide thickness (EOT) of a gate oxide layer.

In the present embodiments, a wet oxide layer grown through a Water Vapor Generator (WVG) method and a dry oxide layer formed through a Rapid Thermal Oxidation (RTO) process were used as a pure gate oxide layer in which plasma nitrogen ions are implanted. Contrary to a torch method which forms H₂O through conventional flaming, the WVG method forms H₂O using catalysis so that it can control the amount of H₂O formed at the same temperature, thereby making it possible to form a thin gate oxide layer to a thickness of approximately 2.0 nm or less. An approximately 18.3 Å thick WVG wet oxide layer was mainly used as the pure gate oxide layer and approximately 16 Å and approximately 18.3 Å thick dry oxide layers were also formed under the same DPN condition and the nitrogen concentration distribution characteristics according to their gate oxide layer forming processes were then compared (see Example FIG. 1). In example FIG. 1, 16 (RTO) and 18.3 (RTO) denote the approximately 16 Å and the approximately 18.3 Å dry oxide layers, respectively, and 18.3 (F) denotes the approximately 18.3 Å thick WVG wet oxide layer.

The WVG wet oxide layer with the same thickness of approximately 18.3 Å is formed by the process having the following conditions of a temperature of approximately 700 to 800° C., N₂=approximately 3.5 to 5.5 slm, H₂/O₂=approximately 0.4 to 0.6 slm/0.4 to 0.6 slm, a pressure of approximately 80 to 120 torr, and a process time of approximately 3 to 10 minutes. Also, the dry oxide layers with two thicknesses of approximately 18.3 Å and approximately 16 Å are formed by a Rapid Thermal Oxidation (RTO) process at two temperatures of approximately 912° C. and approximately 855° C. under process conditions including N₂=approximately 5 to 15 slm, a pressure of approximately 80 to 120 torr, and a process time of approximately 20 to 60 seconds.

Plasma nitrogen ion implantation, which is also referred to as plasma nitridation, was performed through a Decoupled Plasma Nitridation (DPN) process and nitrogen concentration is changed by varying conditions of the DPN process such as RF power, a duty cycle, a pressure, and a process time.

The following table (Table 1) shows details of various process conditions, which include an oxide layer thickness (THK) of approximately 16 Å or 18.3 Å, RF power (P(W)) of approximately 200 to 800 W, a duty cycle (Duty %) of approximately 20 to 100%, a pressure of approximately 10 to 30 mtorr, and a process time of approximately 30 to 100 seconds. Here, the term “duty cycle” refers to the ratio of an interval, during which RF power is maintained at the highest level, to one period of the RF power. For example, partially turning on the power can minimize damage to the gate oxide layer by plasma.

TABLE 1

| | THK (Å) | P (W) | Duty % | P (mtorr) | time (sec.) |
|---|---|---|---|---|---|
| 1 | 18.3 | 200 | 20 | 10 | 75 |
| 2 | 18.3 | 200 | 20 | 10 | 40 |
| 3 | 18.3 | 400 | 20 | 30 | 75 |
| 4 | 18.3 | 400 | 20 | 20 | 75 |
| 5 | 18.3 | 400 | 20 | 10 | 10 |
| 6 | 18.3 | 400 | 20 | 10 | 30 |
| 7 | 18.3 | 400 | 20 | 10 | 100 |
| 8 | 16 | 400 | 20 | 10 | 75 |
| 9 | 18.3 | 400 | 20 | 10 | 75 |
| 10 | 18.3 | 400 | 20 | 10 | 75 |
| 11 | 18.3 | 400 | 20 | 10 | 80 |
| 12 | 18.3 | 400 | 20 | 10 | 70 |
| 13 | 18.3 | 380 | 20 | 10 | 75 |
| 14 | 18.3 | 420 | 20 | 10 | 75 |
| 15 | 18.3 | 400 | 20 | 11 | 75 |
| 16 | 18.3 | 400 | 20 | 9 | 75 |
| 17 | 18.3 | 400 | 40 | 10 | 75 |
| 18 | 18.3 | 800 | 20 | 10 | 75 |
| 19 | 18.3 | 400 | 100 | 10 | 75 |

Example FIG. 2 is a process flow diagram schematically illustrating the flow of a process using DPN equipment 10. The process is performed in the following manner. First, if a wafer is introduced into a chamber 6, then it is loaded onto a chuck 2 with a voltage of approximately 800V and a plasma nitridation process is then performed on it using N₂ gas. The plasma nitridation process implants plasma nitrogen ions into the wafer surface using approximately 12.56 MHz RF power in a nitrogen atmosphere. As a subsequent process, a post-nitridation annealing (PNA) process is performed to recover damage that has been done to the surface of a gate oxide layer during the DPN process and to prevent a reduction in the nitrogen concentration that would otherwise occur as nitrogen ions are discharged into the air. The DPN chamber 6 includes a spherical, dome-shaped induction coil 4 to maximize the plasma density and efficiency.

The DPN process was performed on separate samples under different conditions such as those of Table 1 and the PNA process was performed under process conditions including a temperature of approximately 900 to 1100° C., O₂=approximately 300 to 500 sccm, N₂=approximately 3.5 to 5.5 slm, a pressure of approximately 3 to 10 torr, and a process time of approximately 5 to 50 seconds. The nitrogen concentration of every prepared sample was analyzed using X-ray Photoelectron Spectroscopy (XPS) equipment and the thickness and the uniformity were measured using Rudolph's S200 diffusion equipment.

Example FIG. 3 is a graph showing results of concentration analysis, using XPS, of a wafer into which nitrogen was implanted using DPN equipment. The measurement method was to measure 10 points of the wafer from the bottom to the top with respect to the Y axis of the wafer. It can be seen from example FIG. 3 that, on average, lower nitrogen concentration was measured at positions closer to the edge of the wafer and higher and uniform nitrogen concentration was measured around the center of the wafer. Nitrogen concentration exhibited a tendency to be very low at the top of the wafer, which may be an effect caused by a pumping port arrangement.

Example FIG. 4A is a graph showing a change in the uniformity of nitrogen concentration according to the nitrogen concentration of a gate oxide layer and example FIGS. 4B and 4C are graphs showing changes in the uniformity of nitrogen concentration according to the thickness (Tox) and the thickness uniformity (Tox Uniformity) of a gate oxide layer, respectively. As shown in example FIGS. 4A and 4C, a uniformity index expressed in percentage increases as the uniformity decreases (or is lowered) and decreases as the uniformity increases (or is improved). Collection of the measurement results of all samples of Table 1 showed that nitrogen distribution in the wafer became more uniform as the nitrogen concentration increased. In addition, thickness measurement results using an optical measurement method showed that the thickness of the gate oxide layer exhibited a tendency to increase and the uniformity of nitrogen concentration in the gate oxide layer exhibited a tendency to be improved as the nitrogen concentration increases.

Example FIGS. 5A to 5D are graphs showing changes in both the thickness and the nitrogen concentration as the plasma density of a DPN process increases. Experiments were performed with plasma nitrogen concentration that changes as the RF power changes in the range of approximately 200 to 800 W and the duty cycle changes in the range of approximately 20 to 100%. The purpose of using the duty cycle when performing plasma nitridation is to minimize plasma damage to the gate oxide layer and to form a shallow junction on the oxide layer surface using nitrogen. As can be seen from example FIGS. 5A to 5D, nitrogen content in the gate oxide layer increases as the plasma density increases. In addition, the thickness of the gate oxide layer measured by an optical measurement method exhibited a tendency to increase and the thickness uniformity index of the gate oxide layer exhibited a tendency to decrease as the nitrogen concentration increases.

Example FIGS. 6A and 6B are graphs illustrating the influence of the process pressure on changes in the nitrogen concentration and the thickness (Tox) of the gate oxide layer. Experiments were performed under conditions including a pressure of approximately 10 to 30 mtorr. We observed that the nitrogen concentration decreased as the pressure increased as shown in example FIGS. 6A and 6B, contrary to the change tendency of the nitrogen concentration according to the RF power and the duty cycle. This is because an increase in the process pressure causes recombination between ions formed in plasma, thereby reducing the plasma density. On the other hand, changes in the thickness of the gate oxide layer and the thickness uniformity exhibited the same tendencies as in the above example as the nitrogen concentration changed.

Example FIGS. 7A and 7B are graphs illustrating the influence of the process time on changes in the nitrogen concentration and the thickness of the gate oxide layer. The amount of implanted nitrogen exhibited a tendency to increase as the process time increases with the same plasma density and the thickness of the gate oxide layer also exhibited a tendency to increase, as can be seen from example FIGS. 7A and 7B. On the other hand, the thickness uniformity index of the gate oxide layer increased as the amount of nitrogen increased, contrary to the tendency of the above examples, and thus it can be understood that the uniformity characteristics of the gate oxide layer are lowered when it is exposed for a long time under the same plasma density.

Example FIGS. 8A to 8F are graphs showing changes in the nitrogen concentration and changes in the thickness of the gate oxide layer when various process parameters of the plasma nitridation process are changed slightly in a small range of approximately 5 to 10% from their reference conditions (i.e., an RF power of approximately 400 W, a duty cycle of approximately 20%, a pressure of approximately 100 mtorr, and a process time of approximately 75 seconds). Here, the change in the nitrogen concentration exhibited a specific tendency to be associated with changes of the various process parameters in the small range, whereas the thickness of the gate oxide layer and the thickness uniformity did not exhibit a specific tendency according to changes in the amount of nitrogen and in the process parameters. The first reason for this difference is that the degree of dispersion of nitrogen concentration in the wafer is high so that the thickness difference is not well detected in the small range. The second reason is that, due to movement of the wafer to optical thickness measurement equipment after a DPN process is performed and delay time caused by the time difference between measurements, organic material in the air are attached to the surface of the oxide layer, thereby reducing the measurement accuracy of the thickness and the thickness uniformity. Example FIGS. 9A and 9B are graphs showing the thickness of a nitrogen-implanted gate oxide layer of a wafer, which was measured at regular time intervals with the wafer exposed to the air. It can be seen that the measured thickness and thickness uniformity index of the oxide layer increases as time passes and that the thickness of the oxide layer rapidly increases in 5 minutes after it is exposed to the air.

Example FIG. 10 is a graph showing changes in the thicknesses of two samples due to delay time when a DPN process is performed on the two samples with different RF power levels. It can be seen from example FIG. 10 that the overall thickness difference between the two samples is uniform since the organic growth speed according to the time during which they are exposed to the air is uniform regardless of the concentration difference of nitrogen implanted into the two oxide layers.

Example FIG. 11 is a graph showing a comparison of the measured thicknesses of two samples according to RF power. It can be seen from example FIG. 11 that the two samples exhibit a uniform thickness difference ΔTox under the same conditions and thus the optical thickness measurement results can represent the amount of nitrogen.

As is apparent from the above description, the embodiments provide a method for forming a gate insulating layer of a MOS transistor, which has a variety of features and advantages. For example, when a plasma nitridation process is performed, the concentration of nitrogen in a gate oxide layer increases as RF power, a duty cycle, and a process time increases (i.e., the concentration of nitrogen is proportional to these parameters) and the concentration of nitrogen decreases as a process pressure increases (i.e., the concentration of nitrogen is inversely proportional to the process pressure). In addition, the optically measured thickness of the gate oxide layer increases and becomes more uniform as the concentration of nitrogen increases and the uniformity is exceptionally reduced only when the process time increases. The tendency of the optically measured thickness to increase as the nitrogen concentration increases distinctly appears in a wide area but not in a small, local area. Especially, when a gate oxide layer into which a large amount of nitrogen has been implanted through plasma nitridation is exposed to the air, organic materials are attached to the surface of the gate oxide layer and the initial attachment is very rapid to exert a significant influence on measurement errors of the thickness of the oxide layer. Measurement results of the thickness of the oxide layer according to the level of RF power, which is most influential in the change of nitrogen concentration, showed a tendency of the thickness to change uniformly due to organic materials at the same time during which the oxide layer is exposed to the air. In addition, thickness measurement results obtained through a lot of monitoring under the same conditions showed a uniform thickness difference between samples with different RF power levels. From these facts, it is apparent that optical thickness measurement is an effective method to analyze the concentration of nitrogen.

What is claimed is:

1. A method for forming a gate insulating layer of a semiconductor device, the method comprising:
forming an oxide layer on a semiconductor substrate;
implanting plasma nitrogen ions into the oxide layer; and
performing heat treatment on the nitrogen ion-implanted oxide layer to eliminate damage to a surface of the oxide layer.

2. The method of claim 1, wherein the semiconductor device comprises a Metal Oxide Semiconductor (MOS) transistor.

3. The method of claim 1, wherein the oxide layer is formed by performing a Water Vapor Generator (WVG) process.

4. The method of claim 3, wherein the WVG process is performed for approximately 3 to approximately 10 minutes at a temperature of approximately 700 to approximately 800° C.

5. The method of claim 4, wherein N₂ is between approximately 3.5 to approximately 5.5 slm and H₂/O₂ is between approximately 0.4 to approximately 0.6 slm/approximately 0.4 to 0.6 slm.

6. The method of claim 5, wherein the WVG process is performed at a pressure of approximately 80 to approximately 120 torr.

7. The method according to claim 1, wherein the oxide layer is formed by performing a Rapid Thermal Oxidation (RTO) process.

8. The method of claim 7, wherein the RTO process is performed for approximately 20 to approximately 60 seconds at a temperature of approximately 855 to approximately 912° C.

9. The method of claim 8, wherein N₂ is between approximately 5 to approximately 15 slm.

10. The method of claim 9, wherein the RTO process is performed at a pressure of approximately 80 to approximately 120 torr.

11. The method of claim 1, wherein the nitrogen ions are implanted according to a Decoupled Plasma Nitridation (DPN) method.

12. The method of claim 11, wherein the nitrogen ions are implanted under conditions including RF power of approximately 200 to approximately 800 W and a duty cycle between approximately 20 to approximately 100%.

13. The method of claim 12, wherein the nitrogen ions are implanted at a pressure of approximately 10 to approximately 30 mtorr.

14. The method of claim 13, wherein the nitrogen ions are implanted with a process time of between approximately 30 to approximately 100 seconds.

15. The method according to claim 1, wherein the nitrogen ions are implanted under conditions including RF power of approximately 200 to approximately 400 W, a duty cycle of approximately 20%, a pressure of approximately 10 to approximately 30 mtorr, and a process time of approximately 40 to approximately 100 seconds.

16. A gate insulating layer of a semiconductor device comprising:
an oxide layer on a semiconductor substrate;
implanted plasma nitrogen ions within the oxide layer; and
a heat treated surface of the nitrogen ion-implanted oxide layer thereby reducing damage to the surface.

17. The gate insulating layer of claim 16, wherein the semiconductor device comprises a Metal Oxide Semiconductor (MOS) transistor.

18. The gate insulating layer of claim 16, wherein the nitrogen ions are implanted under conditions including RF power of approximately 200 to approximately 400 W, a duty cycle of approximately 20%, a pressure of approximately 10 to approximately 30 mtorr, and a process time of approximately 40 to approximately 100 seconds.

19. The gate insulating layer of claim 16, wherein the oxide layer has a thickness between approximately 16 Å and approximately 18.3 Å.

20. The gate insulating layer of claim 16, wherein the oxide layer has a thickness of approximately 18.3 Å
